(19) United States
(12) Patent Application Publication
(10) Pub. No.: US 2010/0144143 A1
(43) Pub. Date: Jun. 10, 2010

(54) METHOD OF MANUFACTURING SEMICONDUCTOR DEVICE

(75) Inventor: Hideaki Okamura, Toyama (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/703,971

(22) Filed: Feb. 11, 2010

Related U.S. Application Data
(63) Continuation of application No. PCT/JP2009/003061, filed on Jul. 2, 2009.

(30) Foreign Application Priority Data
Jul. 10, 2008 (JP) 2008-179656

(51) Int. Cl. H01L 21/768

(52) U.S. Cl. 438/675; 257/E21.585

(57) ABSTRACT

A SiOC film 7 exposed at the bottom of a contact hole 11 is changed to an altered layer 12 after the contact hole 11 is formed, so that a selection ratio of the altered layer 12 and a semiconductor substrate 1 can be increased and the altered layer 12 can be selectively removed by etching. Thus it is possible to suppress an amount of etching on a base substrate and form a contact while suppressing leakage from the substrate even when stacked layers are displaced from each other.

### TECHNICAL FIELD

The present invention relates to a method of manufacturing a semiconductor device by which a contact hole is formed on the semiconductor device.

### BACKGROUND ART

In recent years, as semiconductor devices have been reduced in size, margins for stacking layers have been further reduced in a lithography process to increase the degree of integration of transistors. Moreover, the diffusion layers of semiconductor substrates have been further reduced in depth. A contact for connecting wiring and a semiconductor substrate is formed by dry etching an interlayer insulating film to form a contact hole and embedding a conductive material into the contact hole. In the lithography process, however, substantially no margin is provided for stacking layers, so that the contact hole may be displaced from a source/drain region. Further, when the interlayer insulating film is etched, over etching is performed in consideration of a film thickness and variations in etch rate, so that a diffusion layer on a surface of the substrate is also etched. At this point, when an etching amount of a base substrate exceeds the depth of the diffusion layer, leakage occurs from the contact to the substrate, causing a device failure. For this reason, when the contact hole is formed, it is necessary to suppress an amount of etching on the semiconductor substrate.

Referring to FIGS. 5A to 5E and 6A to 6C, the following will describe a method of manufacturing a semiconductor device according to an embodiment of the prior art.

FIGS. 5A to 5E and 6A to 6C are process sectional views for explaining the method of manufacturing the semiconductor device according to the prior art.

As shown in FIG. 5A, in the element formation region of a semiconductor substrate 1, an extension region 2, a source/drain region 3, a gate oxide film 4, a polysilicon gate electrode 5, and an LDD side wall 6 are formed.

Next, as shown in FIG. 5B, a silicon nitride film 14 is stacked with a thickness of 30 nm as an etching stopper film on the semiconductor substrate 1 by using a low pressure CVD method. The silicon nitride film 14 is used as an etching stopper film because a material of a silicon oxide film is generally used for an interlayer insulating film in the subsequent step, a selection ratio to the silicon oxide film can be easily obtained during contact etching, and contamination and so on are not likely to occur on the device.

After that, as shown in FIG. 5C, an SA-NSG film 8 is stacked with a thickness of 500 nm as an interlayer insulating film on the silicon nitride film 14, and the SA-NSG film 8 is polished and flattened by 200 nm by using a CMP method.

Next, as shown in FIG. 5D, an antireflection coating 9 made of an organic film material is applied with a thickness of 50 nm, and then a contact pattern is formed using an ArF resist 10.

After that, as shown in FIG. 5E, the antireflection coating 9 and the SA-NSG film 8 are dry etched according to the pattern of the ArF resist 10 until the silicon nitride film 14 is exposed, so that a contact hole 11 is formed on the gate electrode 5. As a condition for dry etching, a double-frequency application capacity-coupling etching apparatus is used. The antireflection coating 9 is dry etched on conditions that the flow rate of CF₄ is 100 sccm, power applied to an upper electrode is 1000 W, power applied to a lower electrode is 300 W, and a gas pressure is 10 Pa. The SA-NSG film 8 is dry etched on conditions that the flow rate of C₄F₆ is 10 sccm, the flow rate of Ar is 1000 sccm, the flow rate of O₂ is 5 sccm, power applied to the upper electrode is 800 W, power applied to the lower electrode is 600 W, and a gas pressure is 10 Pa. At this point, a selection ratio is obtained such that the silicon nitride film 14 is not penetrated by contact etching. Thus the silicon nitride film 14 acts as an etching stopper film.

Next, as shown in FIG. 6A, the silicon nitride film 14 is dry etched with a selection ratio to the semiconductor substrate 1. Dry etching is performed using a parallel-plate capacity-coupling dry etching apparatus on conditions that the flow rate of CHF₃ is 50 sccm, the flow rate of Ar is 1000 sccm, the flow rate of oxygen is 5 sccm, discharged power is 200 W, and a gas pressure is 10 Pa. Although the selection ratio of the silicon nitride film 14 and the semiconductor substrate 1 serving as a base substrate is to be set high but cannot be set so high (up to about 3) because a high selection ratio may stop etching on the silicon nitride film 14. For example, when the silicon nitride film 14 with a thickness of 30 nm is dry etched, the substrate is etched by no less than 6 nm in a state in which an amount of over etching is 50% of the thickness during etching and a selection ratio of the silicon nitride film 14 and the base substrate is 2.5. The amount of etching is sufficiently larger than the depth (up to 3 nm) of the diffusion layer of the extension region 2. During the formation of the contact pattern in the lithography process (FIG. 5D), in the case where the stacked layers are displaced from each other such that the position of the contact pattern is displaced from the top of the gate electrode to the source/drain region 3, a point 15 protrudes from the extension region 2 as shown in FIG. 6A.

After that, as shown in FIG. 6B, the antireflection coating 9 and the ArF resist 10 are removed.

Next, as shown in FIG. 6C, a conductive material 13 serving as a contact material is charged into the formed contact hole 11 to form a contact. At this point, the conductive material 13 causes a leakage current from the substrate through the point 15 which protrudes from the extension region 3.

In order to address these problems, in the prior art, a polysilicon film and a silicon nitride film serving as etching stopper films are treated by wet etching using a chemical solution and isotropic etching using CF₄ gas plasma, so that etching on a substrate is suppressed (for example, see patent document 1). Further, by using WSx as an etching stopper film, a contact can be secured in a source/drain region even when stacked layers are displaced from each other (for example, see patent document 2).

### CITATION LIST

### Patent Document

Patent Document 1: Japanese Patent Laid-Open No. 4-048644
Patent Document 2: Japanese Patent Laid-Open No. 9-321280

### SUMMARY OF THE INVENTION

### Problems to be Solved by the Invention

However, as semiconductor devices have been reduced in size, dimensions including a pitch between gate electrodes and a contact hole diameter have been also reduced. Thus, in wet etching using a chemical solution and isotropic etching using CF₄ gas plasma, when a conductive material is embedded into a contact hole, a void may be generated by side etching on an etching stopper film, so that the conductive material may be insufficiently embedded and a device yield may disadvantageously decrease. Moreover, in a method using WSx, patterning on a WSx film used as a stopper film has been more difficult as semiconductor devices have been reduced in size, causing another processing problem such as residual WSx.

In view of the foregoing problems, an object of the present invention is to suppress etching on a base substrate at the bottom of a contact hole without causing a processing problem on the contact hole when the contact hole is formed.

### Means for Solving the Problems

In order to attain the object, a method of manufacturing a semiconductor device according to the present invention, when a contact is formed on the semiconductor device, the method including: forming one of a semiconductor element and wiring on a semiconductor substrate; stacking a SiOC film over the semiconductor substrate including the top surface of the semiconductor element and the top surface of the wiring; stacking an interlayer insulating film on the SiOC film; stacking an antireflection coating on the interlayer insulating film; applying photosensitive resin on the antireflection coating and then forming an opening in the contact hole formation region of the photosensitive resin to form the pattern of a contact hole; forming the contact hole by dry etching the antireflection coating and the interlayer insulating film according to the pattern of the photosensitive resin until a surface of the SiOC film is exposed; irradiating the overall semiconductor substrate with oxygen gas plasma to alter an exposed part of the SiOC film to an altered layer; dry etching the altered layer to expose a surface of the semiconductor substrate; removing the photosensitive resin and the antireflection coating; and charging a conductive material into the contact hole to form the contact.

Further, a method of manufacturing a semiconductor device according to the present invention, when a contact is formed on the semiconductor device, the method including: forming one of a semiconductor element and wiring on a semiconductor substrate; stacking a SiOC film over the semiconductor substrate including one of the top surface of the semiconductor element and the top surface of the wiring; stacking an interlayer insulating film on the SiOC film; stacking an antireflection coating on the interlayer insulating film; applying photosensitive resin on the antireflection coating and then forming an opening in the contact hole formation region of the photosensitive resin to form the pattern of a contact hole; forming the contact hole by dry etching the antireflection coating and the interlayer insulating film according to the pattern of the photosensitive resin until a surface of the SiOC film is exposed; removing the photosensitive resin and the antireflection coating while irradiating the overall semiconductor substrate with oxygen gas plasma to alter an exposed part of the SiOC film to an altered layer; dry etching the altered layer to expose a surface of the semiconductor substrate; and charging a conductive material into the contact hole to form the contact.

During alteration to the altered layer, the plasma irradiation of oxygen gas may be replaced with plasma irradiation of gas containing an oxygen atom.

### ADVANTAGE OF THE INVENTION

As has been discussed, a SiOC film exposed at the bottom of a contact hole is changed to an altered layer after the contact hole is formed, so that a selection ratio of the altered layer and a semiconductor substrate can be increased and the altered layer can be selectively removed by etching. Thus it is possible to suppress an amount of etching on a base substrate and form a contact while suppressing leakage from the substrate even when stacked layers are displaced from each other.

### BRIEF DESCRIPTION OF THE DRAWINGS

FIG. 1A to 1E is a process sectional drawing for explaining a method of manufacturing a semiconductor device according to a first embodiment;

FIG. 2A to 2D is a process sectional drawing for explaining the method of manufacturing the semiconductor device according to the first embodiment;

FIG. 3A to 3E is a process sectional drawing for explaining a method of manufacturing a semiconductor device according to a second embodiment;

FIG. 4A to 4D is a process sectional drawing for explaining the method of manufacturing the semiconductor device according to the second embodiment;

FIG. 5A to 5E is a process sectional drawing for explaining a method of manufacturing a semiconductor device according to the prior art; and

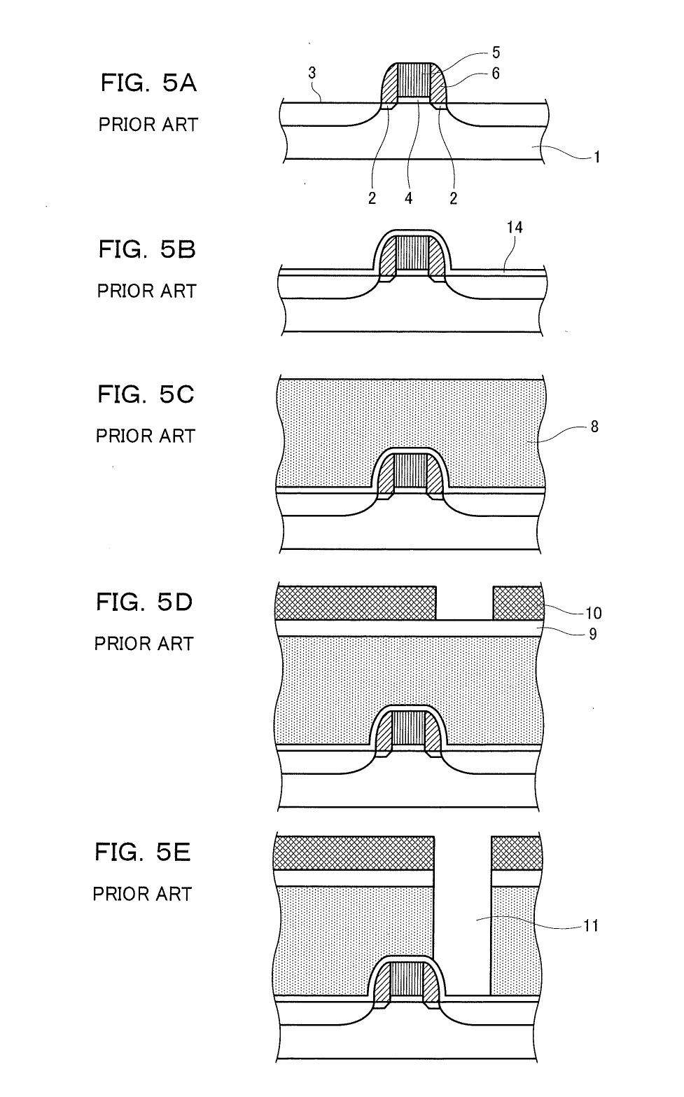

FIG. 6A to 6C is a process sectional drawing for explaining the method of manufacturing the semiconductor device according to the prior art.

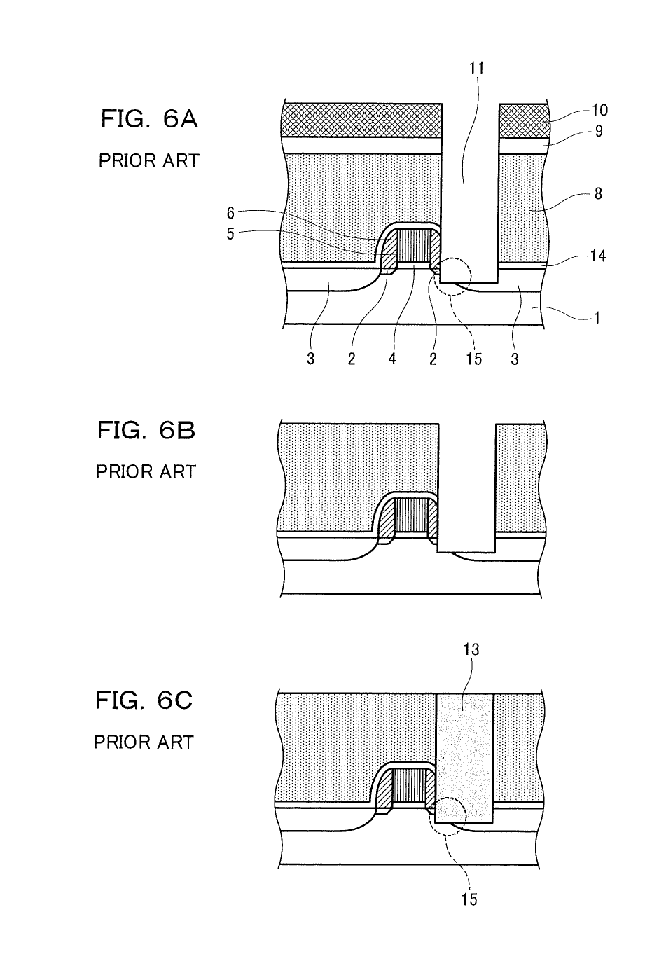

### BEST MODE FOR CARRYING OUT THE INVENTION

### First Embodiment

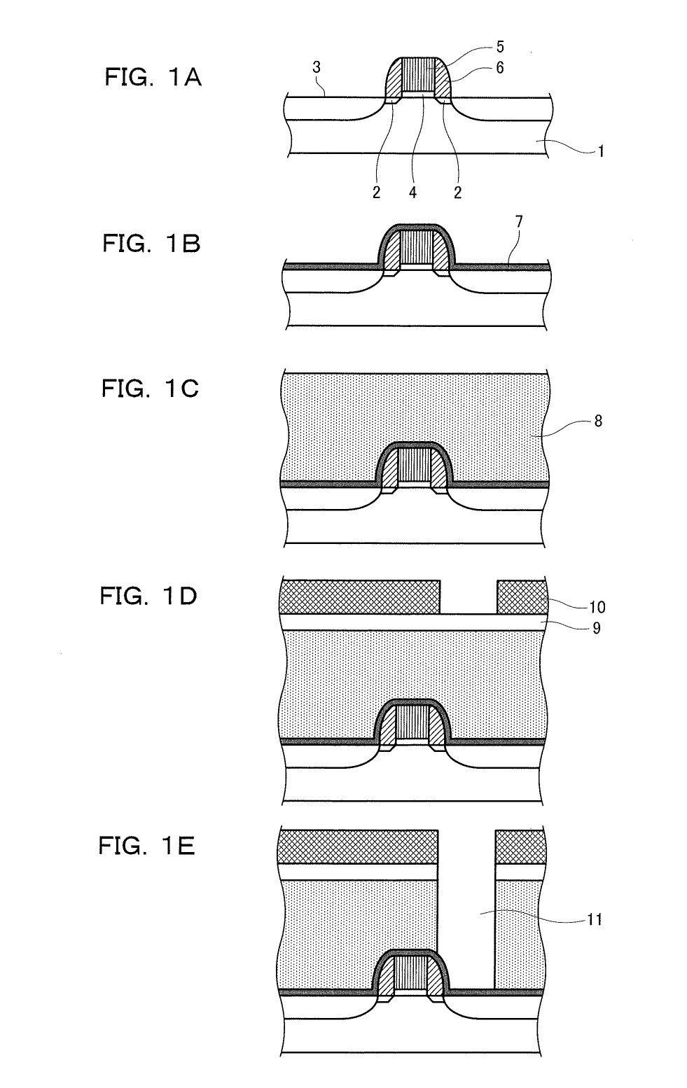

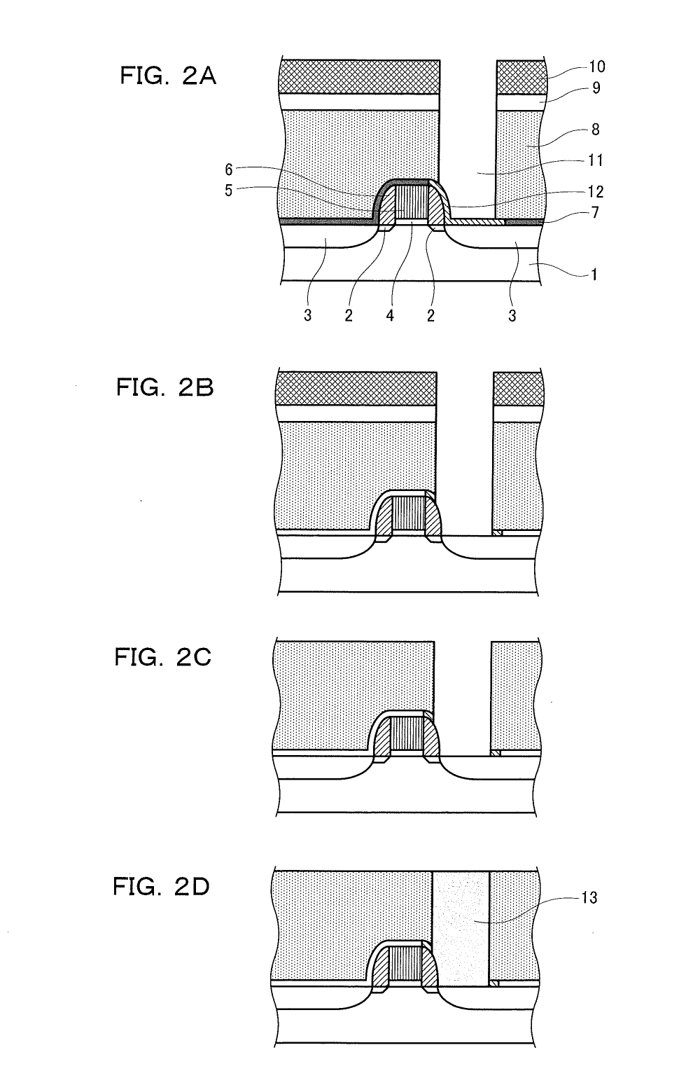

Referring to FIGS. 1A to 1E and 2A to 2D, the following will describe a method of manufacturing a semiconductor device according to a first embodiment of the present invention.

FIGS. 1A to 1E and 2A to 2D are process sectional drawings for explaining the method of manufacturing the semiconductor device according to the first embodiment.

First, as shown in FIG. 1A, an extension region 2, a source/drain region 3, a gate oxide film 4, a polysilicon gate electrode 5, and an LLD side wall 6 acting as an insulating film are formed in an element formation region of a semiconductor substrate 1 to form a semiconductor element.

Next, as shown in FIG. 1B, a SiOC film 7 is stacked with a thickness of 30 nm as an etching stopper film over the semiconductor substrate 1 by using a plasma CVD method. As conditions of plasma CVD, DMDMOS is used as source gas and the film is formed at 300° C. to 450° C.

After that, as shown in FIG. 1C, an SA-NSG film 8 is stacked with a thickness of 500 nm as an interlayer insulating film on the SiOC film 7, and the SA-NSG film 8 is polished and flattened by 200 nm by a CMP method.

Next, as shown in FIG. 1D, an antireflection coating 9 made of an organic film material is applied with a thickness of 50 nm, and then a contact pattern is formed on the antireflection coating 9 as a region immediately above the gate electrode 5 by using an ArF resist 10.

After that, as shown in FIG. 1E, the antireflection coating 9 and the SA-NSG film 8 are dry etched according to the pattern of the ArF resist 10 until the SiOC film 7 is exposed, so that a contact hole 11 is formed on the gate electrode 5. As a condition of dry etching, a double-frequency application capacity-coupling etching apparatus is used. The antireflection coating 9 is dry etched on conditions that the flow rate of CF₄ is 100 sccm, power applied to an upper electrode is 1000 W, power applied to a lower electrode is 300 W, and a gas pressure is 10 Pa. The SA-NSG film 8 is dry etched on conditions that the flow rate of C₄F₆ is 10 sccm, the flow rate of Ar is 1000 sccm, the flow rate of O₂ is 5 sccm, power applied to the upper electrode is 800 W, power applied to the lower electrode is 600 W, and a gas pressure is 10 Pa. At this point, a selection ratio of the SA-NSG film 8 and the SiOC film 7 can be obtained and the SiOC film 7 can be used as an etching stopper film.

Next, as shown in FIG. 2A, the overall semiconductor substrate 1 is irradiated with oxygen plasma. For the plasma irradiation, an inductively coupled plasma apparatus is used. Oxygen plasma is generated to perform treatment in a state in which the flow rate of oxygen gas is 1000 sccm, discharged power is 1000 W, and a gas pressure is 10 Pa. An oxygen radical in plasma removes C from Si—C coupling in the SiOC film 7, forms Si—O coupling, and changes the film quality close to that of a silicon oxide film. In the case of oxygen plasma treatment, it was confirmed that an altered layer was formed with a thickness of up to about 50 nm from a surface of the SiOc film by treatment of 60 seconds. Thus when the SiOC film 7 stacked as a stopper film has a thickness of 30 nm, it is certain that an exposed part is sufficiently altered by the 60-second treatment. In this configuration, an altered layer 12 is a part altered close to the film quality of a silicon oxide film by the 60-second oxygen plasma treatment.

Next, as shown in FIG. 2B, the altered layer 12 is dry etched with a selection ratio to the semiconductor substrate 1. Dry etching is performed using a parallel-plate capacity-coupling dry etching apparatus on conditions that the flow rate of C₄F₈ is 10 sccm, the flow rate of Ar is 1000 sccm, discharged power is 100 W, and a gas pressure is 10 Pa. Generally, when a silicon oxide film and a silicon nitride film are dry etched, fluorocarbon gas is frequently used. When a selection ratio to a base substrate (in this case, a silicon substrate) is obtained, a reaction product (CF polymer film) is stacked on a surface of the base substrate to interfere with etching, thereby reducing an etch rate. However, as an amount of the stacked reaction product increases, the etch rates of the silicon oxide film and the silicon nitride film decrease. According to the present invention, the SiOC film 7 acting as an etching stopper film is altered to the altered layer 12, so that the silicon oxide film contains oxygen atoms. Thus oxygen in the altered layer 12 reacts with carbon of the reaction product during etching and C is removed as expressed in C+2O→CO₂. It is therefore understood that regarding the silicon oxide film, a selection ratio to a base substrate (silicon substrate) can be easily obtained as compared with other materials of a silicon nitride film and so on. Actually, under the dry etching conditions, a selection ratio of the silicon oxide film and the silicon substrate is 15. It is understood that the selection ratio is remarkably improved (the etching amount is reduced to one fifth) from the selection ratio (up to 3) of the silicon nitride film and the base substrate of the prior art method.

After that, as shown in FIG. 2C, the antireflection coating 9 and the ArF resist 10 are removed by aching, and a residual resist and a residual polymer are removed by cleaning using a sulfuric acid-hydrogen peroxide mixture and an ammonia-hydrogen peroxide mixture.

Finally, as shown in FIG. 2D, the formed contact hole 11 is filled with a conductive material 13, which is a contact material, to form a contact.

As has been discussed, according to the first embodiment, the etching stopper film made up of a SiOC film is formed beforehand between the interlayer insulating film and the semiconductor substrate. When the etching stopper film is etched, the stopper film is changed to the altered layer having a similar structure to a silicon oxide film, and then the stopper film is etched. Thus even when a contact hole formation region is displaced from the top of the gate electrode to the source/drain region, it is possible to adopt processing conditions with a high selection ratio to the base substrate. Consequently, it is possible to achieve a processing technique of reducing an etching amount of the base substrate without causing a processing problem on the contact hole and suppress a leakage current from the substrate.

In the foregoing embodiment, in the process of FIG. 2A, the SiOC film 7 is altered using oxygen gas plasma. The SiOC film 7 may be altered using gas containing carbon dioxide and oxygen atoms of water and the like or mixed gas containing at least one of the gas and oxygen. Further, although a surface of the source/drain region 3 is not silicided in the foregoing embodiment, the surface may be silicided.

### Second Embodiment

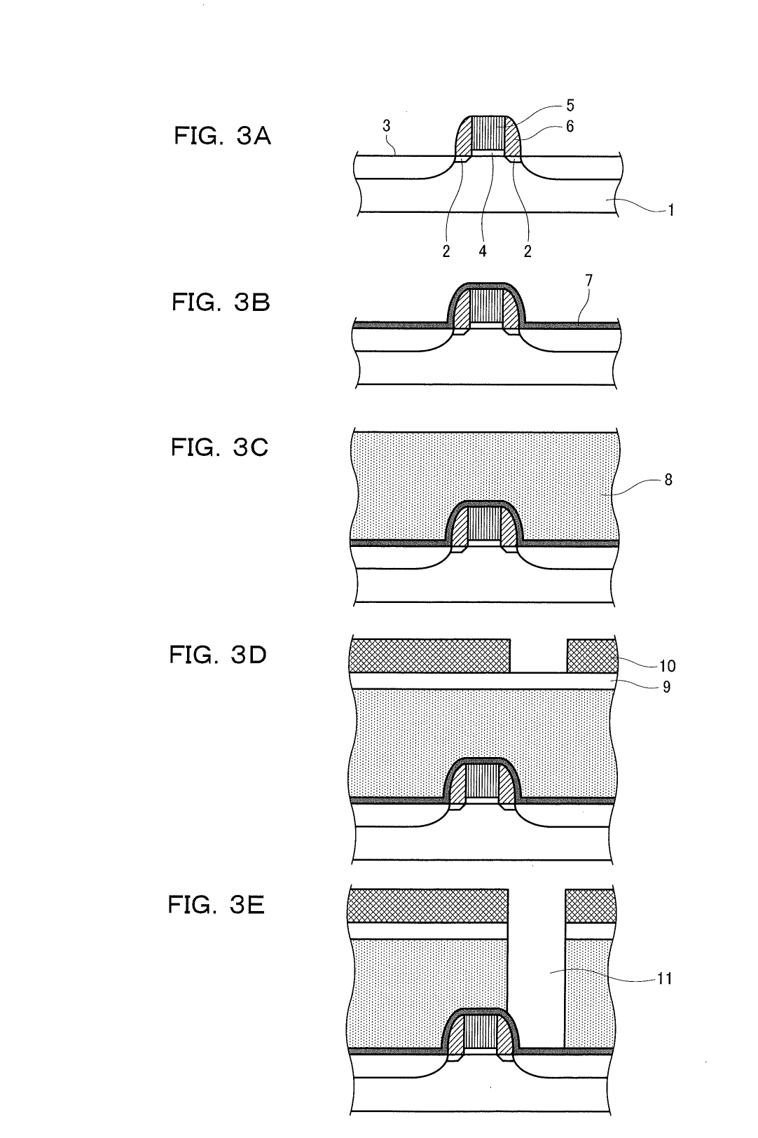

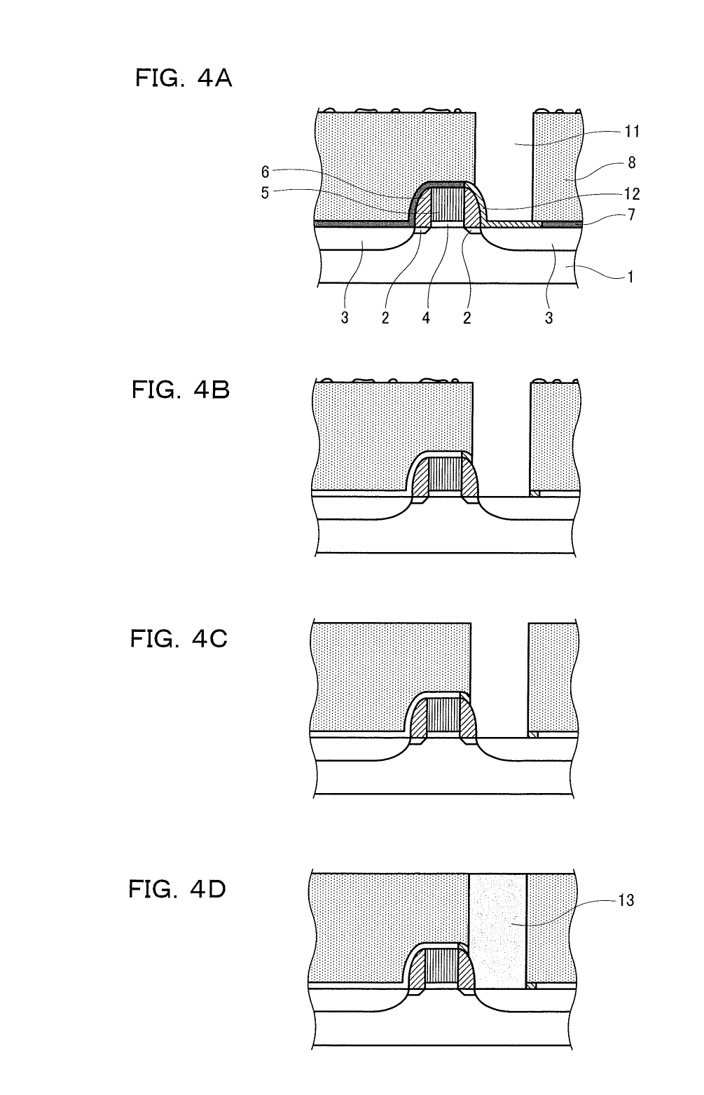

Referring to FIGS. 3A to 3E and 4A to 4D, the following will describe a method of manufacturing a semiconductor device according to a second embodiment of the present invention.

FIGS. 3A to 3E and 4A to 4D are process sectional drawings for explaining the method of manufacturing the semiconductor device according to the second embodiment.

First, as shown in FIG. 3A, an extension region 2, a source/drain region 3, a gate oxide film 4, a polysilicon gate electrode 5, and an LLD side wall 6 acting as an insulating film are formed in an element formation region of a semiconductor substrate 1 to form a semiconductor element.

Next, as shown in FIG. 3B, a SiOC film 7 is stacked with a thickness of 30 nm as an etching stopper film over the semiconductor substrate 1 by using a plasma CVD method. As conditions of plasma CVD, DMDMOS is used as source gas and the film is formed at 300° C. to 450° C.

After that, as shown in FIG. 3C, an SA-NSG film 8 is stacked with a thickness of 500 nm as an interlayer insulating film on the SiOC film 7, and the SA-NSG film 8 is polished and flattened by 200 nm by a CMP method.

Next, as shown in FIG. 3D, an antireflection coating 9 made of an organic film material is applied with a thickness of 50 nm, and then a contact pattern is formed on the antireflection coating 9 as a region immediately above the gate electrode 5 by using an ArF resist 10.

After that, as shown in FIG. 3E, the antireflection coating 9 and the SA-NSG film 8 are dry etched according to the pattern of the ArF resist 10 until the SiOC film 7 is exposed, so that a contact hole 11 is formed on the gate electrode. As a condition of dry etching, a double-frequency application capacity-coupling etching apparatus is used. The antireflection coating 9 is dry etched on conditions that the flow rate of CF₄ is 100 sccm, power applied to an upper electrode is 1000 W, power applied to a lower electrode is 300 W, and a gas pressure is 10 Pa. The SA-NSG film 8 is dry etched on conditions that the flow rate of C₄F₆ is 10 sccm, the flow rate of Ar is 1000 sccm, the flow rate of O₂ is 5 sccm, power applied to the upper electrode is 800 W, power applied to the lower electrode is 600 W, and a gas pressure is 10 Pa. At this point, a selection ratio of the SA-NSG film 8 and the SiOC film 7 can be obtained and the SiOC film 7 can be used as an etching stopper film.

Next, as shown in FIG. 4A, the overall semiconductor substrate 1 is irradiated with oxygen plasma. For the plasma irradiation, an inductively coupled plasma apparatus is used. Oxygen plasma is generated to perform treatment in a state in which the flow rate of oxygen gas is 1000 sccm, discharged power is 1000 W, and a gas pressure is 10 Pa. At this point, the antireflection coating 9 and the ArF resist 10 are also simultaneously removed. An oxygen radical in plasma removes C from Si—C coupling in the SiOC film 7, forms Si—O coupling, and changes the film quality close to that of a silicon oxide film. In the case of oxygen plasma treatment, it was confirmed that an altered layer was formed with a thickness of up to about 50 nm from a surface of the SiOc film by treatment of 60 seconds. When the SiOC film 7 stacked as a stopper film has a thickness of 30 nm, it is certain that an exposed part is sufficiently altered by the 60-second treatment. In this configuration, an altered layer 12 is a part altered close to the film quality of a silicon oxide film by the 60-second oxygen plasma treatment.

Next, as shown in FIG. 4B, the altered layer 12 is dry etched with a selection ratio to the semiconductor substrate 1. Dry etching is performed using a parallel-plate capacity-coupling dry etching apparatus on conditions that the flow rate of C₄F₈ is 10 sccm, the flow rate of Ar is 1000 sccm, discharged power is 100 W, and a gas pressure is 10 Pa. Generally, when a silicon oxide film and a silicon nitride film are dry etched, fluorocarbon gas is frequently used. When a selection ratio to a base substrate (in this case, a silicon substrate) is obtained, a reaction product (CF polymer film) is stacked on a surface of the base substrate to interfere with etching, thereby reducing an etch rate. However, as an amount of the stacked reaction product increases, the etch rates of the silicon oxide film and the silicon nitride film decrease. According to the present invention, the SiOC film 7 acting as an etching stopper film is altered to the altered layer 12, so that the silicon oxide film contains oxygen atoms. Thus oxygen in the altered layer 12 reacts with carbon of the reaction product during etching and C is removed as expressed in C+2O→CO₂. It is therefore understood that regarding the silicon oxide film, a selection ratio to a base substrate (silicon substrate) can be easily obtained as compared with other materials of a silicon nitride film and so on. Actually, under the dry etching conditions, a selection ratio of the silicon oxide film and the silicon substrate is 15. It is understood that the selection ratio is remarkably improved (the etching amount is reduced to one fifth) from the selection ratio (up to 3) of the silicon nitride film and the base substrate of the prior art method.

After that, as shown in FIG. 4C, a residual resist and a residual polymer are removed by cleaning using a sulfuric acid-hydrogen peroxide mixture and an ammonia-hydrogen peroxide mixture.

Finally, as shown in FIG. 4D, the formed contact hole 11 is filled with a conductive material 13, which is a contact material, to form a contact.

As has been discussed, also in the second embodiment, the etching stopper film made up of a SiOC film is formed beforehand between the interlayer insulating film and the semiconductor substrate. When the etching stopper film is etched, the stopper film is changed to the altered layer having a similar structure to a silicon oxide film, and then the stopper film is etched. Thus even when a contact hole formation region is displaced from the top of the gate electrode to the source/drain region, it is possible to adopt processing conditions with a high selection ratio to the base substrate. Consequently, it is possible to achieve a processing technique of reducing an etching amount of the base substrate without causing a processing problem on the contact hole and suppress a leakage current from the substrate.

In the foregoing embodiment, in the process of FIG. 4A, the SiOC film 7 is altered using oxygen gas plasma. The SiOC film 7 may be altered using gas containing carbon dioxide and oxygen atoms of water and the like or mixed gas containing at least one of the gas and oxygen. Further, although a surface of the source/drain region 3 is not silicided in the foregoing embodiment, the surface may be silicided.

Moreover, in the foregoing embodiments, the contact hole is formed on the gate electrode of the semiconductor element. The contact hole may be formed on wiring formed on other regions of the semiconductor element or between semiconductor elements.

### INDUSTRIAL APPLICABILITY

The present invention is useful for a method and so on of manufacturing a semiconductor device by which a contact hole is formed on the semiconductor device and etching of a base substrate can be suppressed at the bottom of the contact hole without causing a processing problem on the contact hole.

1. A method of manufacturing a semiconductor device, when a contact is formed on the semiconductor device, the method comprising:
forming one of a semiconductor element and wiring on a semiconductor substrate;
stacking a SiOC film over the semiconductor substrate including a top surface of the semiconductor element and a top surface of the wiring;
stacking an interlayer insulating film on the SiOC film;
stacking an antireflection coating on the interlayer insulating film;
applying photosensitive resin on the antireflection coating and then forming an opening in a contact hole formation region of the photosensitive resin to form a pattern of a contact hole;
forming the contact hole by dry etching the antireflection coating and the interlayer insulating film according to a pattern of the photosensitive resin until a surface of the SiOC film is exposed;
irradiating the overall semiconductor substrate with oxygen gas plasma to alter an exposed part of the SiOC film to an altered layer;
dry etching the altered layer to expose a surface of the semiconductor substrate;
removing the photosensitive resin and the antireflection coating; and
charging a conductive material into the contact hole to form the contact.

2. A method of manufacturing a semiconductor device, when a contact is formed on the semiconductor device, the method comprising:
forming one of a semiconductor element and wiring on a semiconductor substrate;
stacking a SiOC film over the semiconductor substrate including one of a top surface of the semiconductor element and a top surface of the wiring;
stacking an interlayer insulating film on the SiOC film;
stacking an antireflection coating on the interlayer insulating film;
applying photosensitive resin on the antireflection coating and then forming an opening in a contact hole formation region of the photosensitive resin to form a pattern of a contact hole;
forming the contact hole by dry etching the antireflection coating and the interlayer insulating film according to a pattern of the photosensitive resin until a surface of the SiOC film is exposed;
removing the photosensitive resin and the antireflection coating while irradiating the overall semiconductor substrate with oxygen gas plasma to alter an exposed part of the SiOC film to an altered layer;
dry etching the altered layer to expose a surface of the semiconductor substrate; and
charging a conductive material into the contact hole to form the contact.

3. The method of manufacturing a semiconductor device according to claim 1, wherein during alteration to the altered layer, the plasma irradiation of oxygen gas is replaced with plasma irradiation of gas containing an oxygen atom.

4. The method of manufacturing a semiconductor device according to claim 2, wherein during alteration to the altered layer, the plasma irradiation of oxygen gas is replaced with plasma irradiation of gas containing an oxygen atom.
